(19) United States
(12) Patent Application Publication
(10) Pub. No.: US 2025/0386449 A1
(43) Pub. Date: Dec. 18, 2025

(54) Server System Storage System Mounting System

(71) Applicant: Dell Products L.P., Round Rock, TX (US)

(72) Inventors: Yi-Chang Chen, New Taipei City (TW); Yufeng Lin, Taipei City (TW); Haocheng Ku, Taipei City (TW)

(21) Appl. No.: 18/745,701

(22) Filed: Jun. 17, 2024

(51) Int. Cl. H05K 7/14; H05K 7/20

(52) U.S. Cl. CPC H05K 7/1489; H05K 7/20736

(57) ABSTRACT

A drive mounting system. The drive mounting system includes a connector housing; and, a mounting component physically coupled to the connector housing, the mounting component comprising: a connector aperture portion, the connector aperture portion comprising a connector aperture housing, the connector aperture housing defining a plurality of longitudinally shaped connector apertures, the plurality of longitudinally shaped connector apertures being spaced apart by a predefined pitch, the predefined pitch corresponding to a fixed pitch defined by a connector housing; and, a top panel portion, top panel portion extending substantially perpendicularly from the connector aperture portion.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a storage system which includes a storage device mounting system.

In one embodiment, the invention relates to a mounting component of a drive mounting system, comprising: a connector aperture portion, the connector aperture portion comprising a connector aperture housing, the connector aperture housing defining a plurality of longitudinally shaped connector apertures, the plurality of longitudinally shaped connector apertures being spaced apart by a predefined pitch, the predefined pitch corresponding to a fixed pitch defined by a connector housing; and, a top panel portion, top panel portion extending substantially perpendicularly from the connector aperture portion.

In another embodiment, the invention relates to a drive mounting system comprising: a connector housing; and, a mounting component physically coupled to the connector housing, the mounting component comprising: a connector aperture portion, the connector aperture portion comprising a connector aperture housing, the connector aperture housing defining a plurality of longitudinally shaped connector apertures, the plurality of longitudinally shaped connector apertures being spaced apart by a predefined pitch, the predefined pitch corresponding to a fixed pitch defined by a connector housing; and, a top panel portion, top panel portion extending substantially perpendicularly from the connector aperture portion.

In another embodiment, the invention relates to a system comprising: a processor; a data bus coupled to the processor; a drive; and, a drive mounting system mounting the drive, the drive mounting system comprising: a connector housing; and, a mounting component physically coupled to the connector housing, the mounting component comprising: a connector aperture portion, the connector aperture portion comprising a connector aperture housing, the connector aperture housing defining a plurality of longitudinally shaped connector apertures, the plurality of longitudinally shaped connector apertures being spaced apart by a predefined pitch, the predefined pitch corresponding to a fixed pitch defined by a connector housing; and, a top panel portion, top panel portion extending substantially perpendicularly from the connector aperture portion.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a perspective view of a rear portion of a server type information handling system having a drive system in accordance with the present disclosure.

FIGS. 5A, 5B, 5C, 5D and 5E, generally referred to as FIG. 5, respectively show an exploded view a front perspective view, a rear perspective view, a front view and a side view of a drive mounting system in accordance with the present disclosure.

FIG. 6 shows a perspective view of a rear portion of a server type information handling system having a drive system in accordance with the present disclosure.

FIGS. 7A, 7B, 7C, 7D and 7E, generally referred to as FIG. 7, respectively show an exploded view a front perspective view, a rear perspective view, a front view and a side view of a drive mounting system in accordance with the present disclosure.

FIGS. 8A, 8B, 8C, 8D, 8E, 8F and 8G, generally referred to as FIG. 8, respectively show a front perspective view, a front view, a rear view, a top view, a bottom view, a right view and a left view of a mounting component of a drive mounting system in accordance with the present disclosure.

FIGS. 9A, 9B, 9C, 9D, 9E, 9F and 9G, generally referred to as FIG. 9, respectively show a front perspective view, a front view, a rear view, a top view, a bottom view, a right view and a left view of a mounting component of a drive mounting system in accordance with the present disclosure.

FIG. 10 shows a perspective view of a drive system in accordance with the present disclosure.

FIGS. 11A, 11B, 11C, and 11D, generally referred to as FIG. 11, respectively show a front perspective view, a rear perspective view, a front view and a side view of a drive mounting system in accordance with the present disclosure.

FIGS. 12A, 12B, 12C, 12D, 12E, 12F and 12G, generally referred to as FIG. 12, respectively show a front perspective view, a front view, a rear view, a top view, a bottom view, a right view and a left view of a mounting component of a drive mounting system in accordance with the present disclosure.

### DETAILED DESCRIPTION

Various aspects of the disclosure include an appreciation that it is known to provide information handling systems with devices which conform to specifications such as devices which conform to an Enterprise and Datacenter Standard Form Factor (EDSFF) drive specification. Various aspects of the present disclosure include an appreciation that drives conforming to the EDSFF standard may conform to a plurality of form factors including an EDSFF E1.L (long) form factor, an EDSFF E1.S (short) form factor, an EDSFF E2.L (long) form factor, an EDSFF E2.S (short) form factor, EDSFF E3.L (long) form factor and an EDSFF E3.S (short) form factor. Various aspects of the present disclosure include an appreciation that the EDSFF E3 form factors are generally used in 2U server designs.

Various aspects of the present disclosure include an appreciation that devices which conform to the EDSFF drive specification may be configured with one or more of a plurality of connector configurations. For example, devices which conform to the EDSFF drive specification may be configured with a single connector configuration (referred to as a 1C connector configuration), a double connector configuration (referred to as a 2C connector configuration) or other connector configurations. Various aspects of the present disclosure include an appreciation that devices which conform to the EDSFF drive specification may be configured with one or more of a plurality of slot configurations. For example, devices which conform to the EDSFF drive specification may be configured with a single slot configuration (referred to as a 1T slot configuration), a double slot configuration (referred to as a 2T slot configuration) or other slot configurations.

Various aspects of the present disclosure include an appreciation that it would be desirable to provide a modular EDSFF backplane holder to fulfill different system thermal conditions based on various processor wattages and features installed with different connector and/or drive pitches and different EDSFF drive form factors such as a 1C1T form factor and a 2C2T. Various aspects of the present disclosure include an appreciation that different EDSFF drive form factors can often require different orthogonal-hybrid cable dimensions which can present issues relating to the backplane structure strength.

A system and method are disclosed for providing a storage system which includes a storage device mounting system. In certain embodiments, the storage system and the storage system mounting system conform to a particular storage system specification. In certain embodiments, the storage system specification includes the EDSFF storage system specification. In certain embodiments, the storage device mounting system includes one or more multi-functional modular mounting components.

In certain embodiments, the multi-functional mounting component secures EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitates backplane module installation and removal.

Such a storage device mounting system advantageously provides an extendable and scalable solution that can apply to many similar applications. Such a storage device mounting system advantageously can be adopted by backplanes with various dimensions and pitches, as well as various cable types.

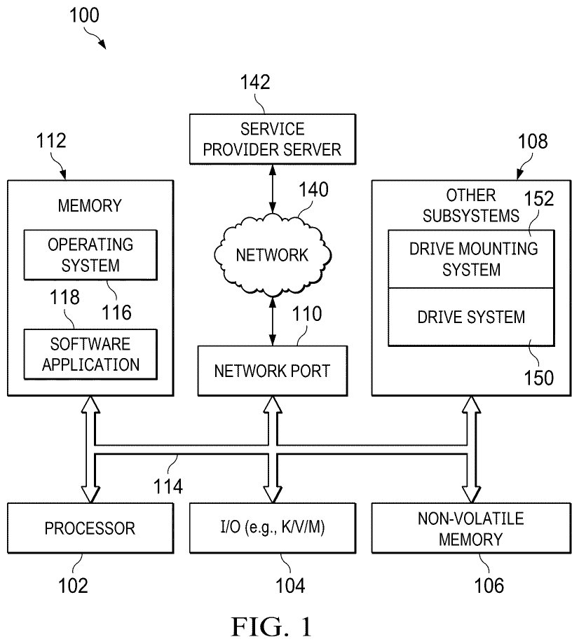

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include an OCP FLOP retention system 150 and an OCP card mounting system 152. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the information handling system 100 includes a storage system 150 which includes at least one storage device 152 and a storage system mounting system 154. In certain embodiments, the storage system 150 conforms to a particular storage system specification. In certain embodiments, the storage device 152 and the storage system mounting system 154 conform to a particular storage system specification. In certain embodiments, the storage system specification includes the EDSFF storage system specification. In certain embodiments, the storage device mounting system includes one or more multi-functional modular mounting components.

In certain embodiments, the multi-functional mounting component secures EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitates backplane module installation and removal.

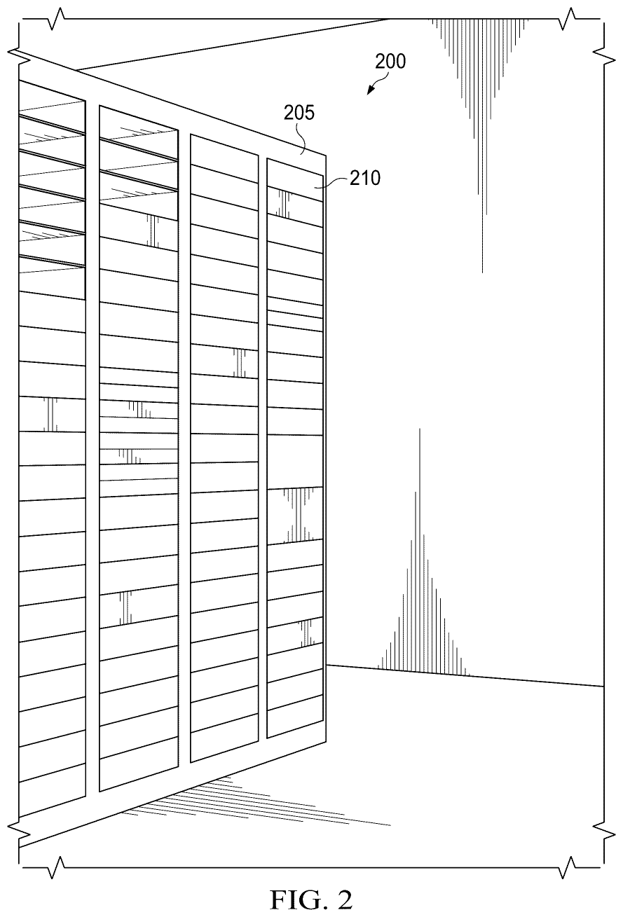

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high.

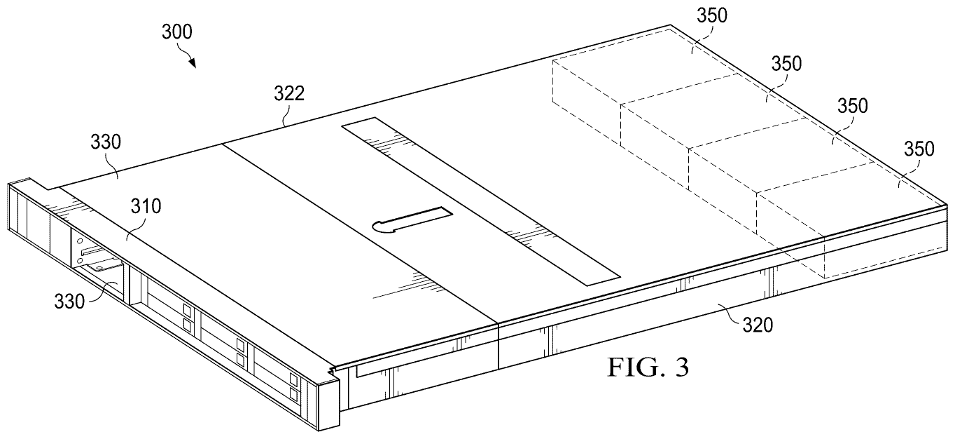

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a storage system bay 350 via which components may be mounted to the blade type information handling system. In certain embodiments, the storage system bay 350 includes a storage system mounting system in which one or more storage devices may be installed.

In certain embodiments, the storage system bay 350 conforms to a particular storage system specification. In certain embodiments, the storage device and the storage system mounting system conform to a particular storage system specification. In certain embodiments, the storage system specification includes the EDSFF storage system specification. In certain embodiments, the storage device mounting system includes one or more multi-functional modular mounting components.

In certain embodiments, the multi-functional mounting component secures EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitates backplane module installation and removal.

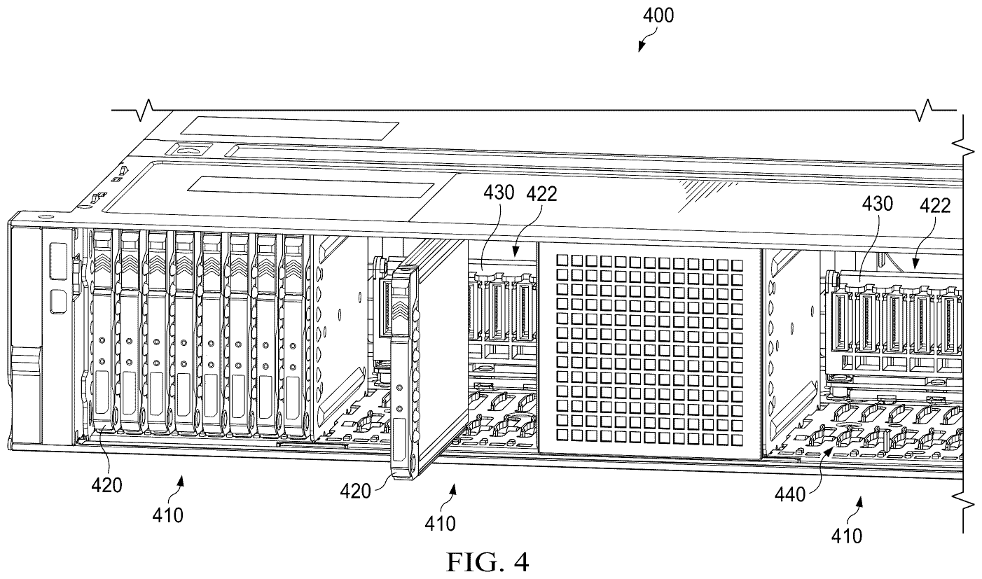

FIG. 4 shows a perspective view of a rear portion 400 of a server type information handling system having one or more drive systems 410 in accordance with the present disclosure.

In certain embodiments, the one or more of the drive systems 410 conform to a particular storage system specification. In certain embodiments, the drive systems include one or more storage devices 420, one or more drive mounting systems 422, or a combination thereof. In certain embodiments, the storage devices 420 and the storage system mounting system 422 conform to a particular storage system specification. In certain embodiments, the storage system specification includes the EDSFF storage system specification. In certain embodiments, the storage device mounting system 422 includes one or more multi-functional modular mounting components 430.

In certain embodiments, the drive mounting system 422 implements one or more slots 440 via which storage devices 420 may be mounted within a respective drive system 410. In certain embodiments, the drive mounting system 422 is orthogonal to the storage devices 410 as the drive mounting system extends substantially perpendicular to the storage devices 410. Accordingly, the drive mounting system 422 is perpendicular to the storage devices 410 at the point of intersection between the drive mounting system 422 and the inserted storage device 410.

In certain embodiments, the multi-functional mounting components 430 secure EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitates backplane module installation and removal. In certain embodiments, the storage devices 410 correspond to a 1T height.

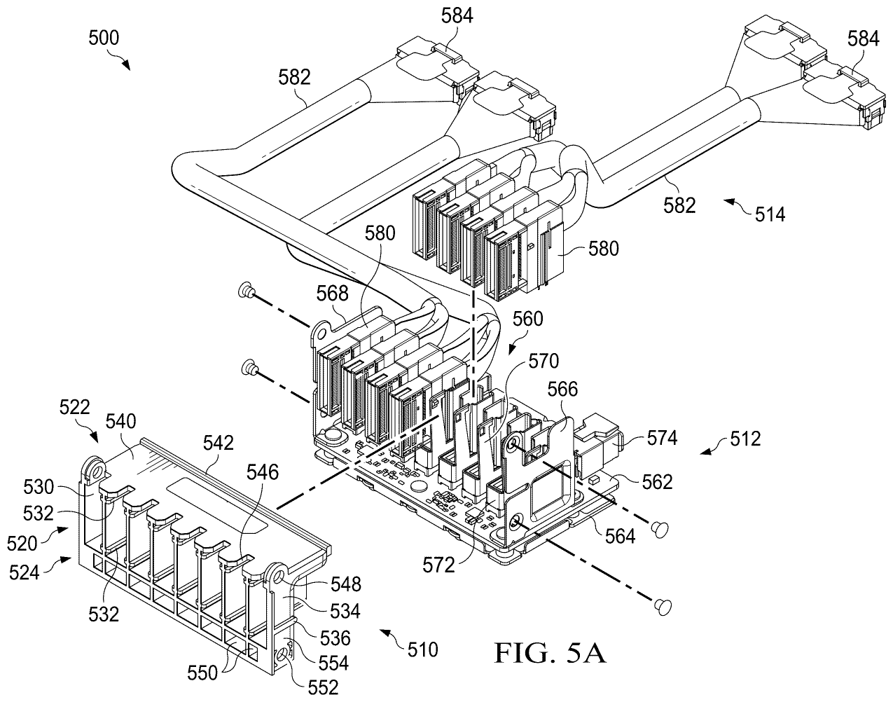

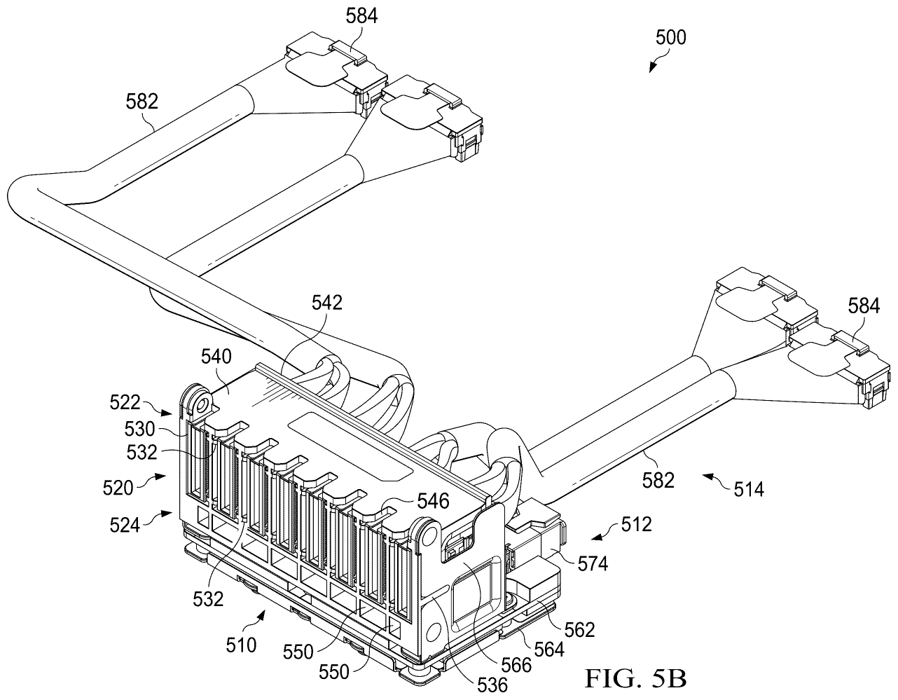

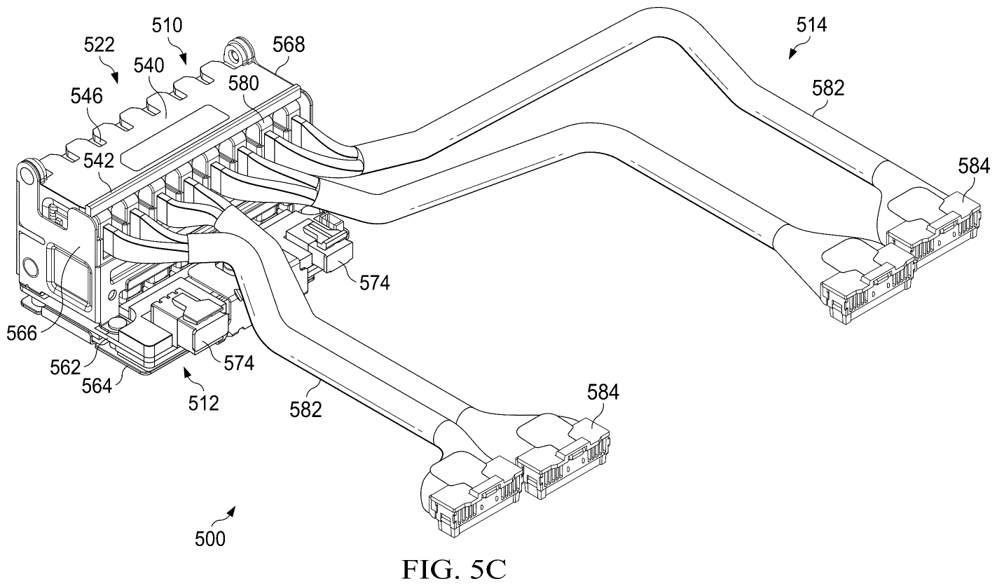

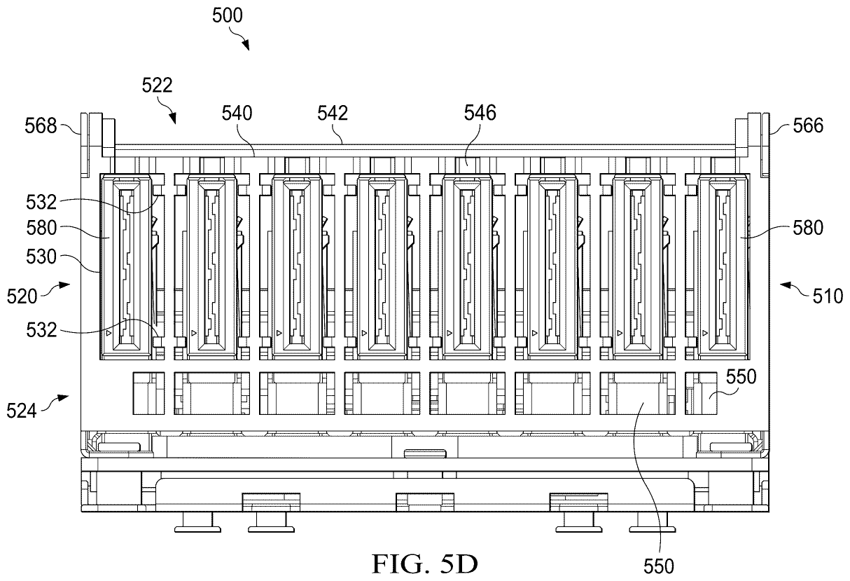

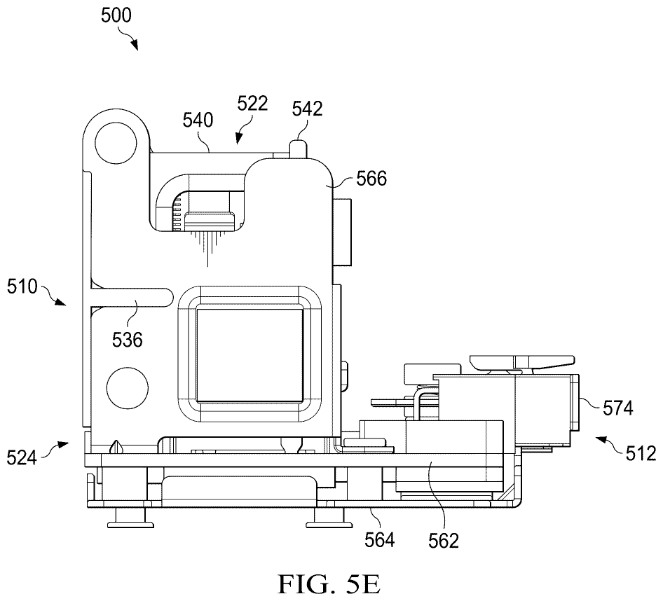

FIGS. 5A, 5B, 5C, 5D and 5E, generally referred to as FIG. 5, a plurality of views of a drive mounting system 500. More specifically, FIG. 5A shows an exploded view a front perspective view of a drive mounting system 500. FIG. 5B shows a front perspective view of a drive mounting system 500. FIG. 5C shows a rear perspective view of a drive mounting system 500. FIG. 5D shows a front view of a drive mounting system 500. FIG. 5E shows a side view of a drive mounting system 500.

In certain embodiments, the drive mounting system 500 includes a mounting component 510, a connector housing 512, and one or more connector cables 514. In certain embodiments, the mounting component 510 is physically coupled to the connector housing 512. In certain embodiments, the connector housing 512 defines a fixed pitch between respective connector receptacle portions 542 of the connector housing 512. In certain embodiments, the mounting component 510, the connector housing 512, the connector cables 514, or a combination thereof, correspond to a 1C1T form factor of the EDSFF specification (also referred to as a single connector, single slot form factor). In certain embodiments, the fixed pitch between the respective connector receptable portions correspond to a 1C1T form factor of the EDSFF specification. In certain embodiments, the drive mounting system 500 is configured to mount up to eight storage devices. In certain embodiments, one or more of the eight storage devices correspond to the EDSFF specification.

In certain embodiments, the mounting component 510 functions as a mounting component. In certain embodiments, the mounting component 510 includes a connector aperture portion 520, a top panel portion 522, a bottom portion 524, or a combination thereof. In certain embodiments, the connector aperture portion 520 is contiguous with the top panel portion 522. In certain embodiments, the top panel portion 522 extends substantially perpendicularly from the connector aperture portion 520. In certain embodiments, the connector aperture portion 520 is contiguous with the bottom panel portion 524. In certain embodiments, the bottom panel portion extends substantially linearly from the connector aperture portion 520. In certain embodiments, the connector aperture portion 520, the top panel portion 522, the bottom portion 524, or a combination thereof, are configured from a single piece of material. In certain embodiments, the connector aperture portion 520, the top panel portion 522, the bottom portion 524, or a combination thereof, are configured from plastic.

In certain embodiments, the connector aperture portion 520 includes a connector aperture portion housing which defines one or more longitudinally shaped connector apertures 530. In certain embodiments, the one or more longitudinally shaped connector apertures 530 are spaced apart by a predefined pitch. In certain embodiments, the predefined pitch corresponds to the fixed pitch defined by the connector housing 512. In certain embodiments, the connector apertures 530 include one or more side wall connector apertures, one or more interior connector apertures, or a combination thereof. In certain embodiments, the one or more side wall connector apertures are positioned at a side wall of the mounting component. In certain embodiments, the side wall connector apertures include a left side wall connector aperture, a right side wall connector aperture, or a combination thereof. In certain embodiments, the interior connector apertures are positioned between the one or more side wall apertures.

In certain embodiments, the one or more longitudinally shaped connector apertures 530 include one or more rib projections 532. In certain embodiments, the rib projections 532 include a top rib projection, a bottom rib projection, or a combination thereof. In certain embodiments, the one or more side wall connector apertures have a corresponding side wall connector aperture rib configuration. In certain embodiments, the one or more interior connector apertures have a corresponding interior connector aperture rib configuration.

In certain embodiments, the connector aperture portion 520 defines side recesses 534. In certain embodiments, the side recesses 534 mate with an inside edge of a respective side wall of the connector housing 512. In certain embodiments, one or both sides of the connector aperture portion 520 include respective mating projections 536. In certain embodiments, the respective mating projections 536 mate with a slot defined by a respective side wall of the connector housing 512.

In certain embodiments, the top portion 522 includes a top portion panel 540 which extends substantially perpendicularly from the connector aperture portion housing. In certain embodiments, the top portion panel 540 includes a rib component 542. In certain embodiments, the rib component 542 extends across a rear edge of the top panel portion 540. In certain embodiments, the top portion panel 540 defines one or more slots 546. In certain embodiments, the one or more slots 546 correspond to respective connector apertures 530. In certain embodiments, the one or more slots 546 enable observation of whether a connector is installed in a respective connector position of connector housing 612. In certain embodiments, the top portion 522 includes fastener receptors 548 to which a top set of fasteners attach the mounting component 510 to the connector housing 512. In certain embodiments, the top portion 522 enhances the structure integrity of the mounting component 510.

In certain embodiments, the bottom portion 524 includes a bottom portion housing which defines one or more airflow apertures 550. In certain embodiments, the some or all of the one or more airflow apertures 550 are spaced apart by a predefined pitch. In certain embodiments, the predefined pitch corresponds to the fixed pitch defined by the connector housing 512. In certain embodiments, the airflow apertures 550 include one or more side wall connector apertures, one or more interior connector apertures, or a combination thereof. In certain embodiments, the one or more side wall connector apertures are positioned at a side wall of the mounting component 510. In certain embodiments, the side wall connector apertures 552 include a left side wall connector aperture, a right side wall connector aperture, or a combination thereof. In certain embodiments, the interior connector apertures are positioned between the one or more side wall apertures. In certain embodiments, the one or more side wall apertures are positioned next to a side wall portion of the bottom portion housing. In certain embodiments, the bottom portion 524 includes fastener receptors to which a bottom set of fasteners attach the mounting component 510 to the connector housing 512. In certain embodiments, the bottom portion 524 defines side recesses 554. In certain embodiments, the side recesses mate with an inside edge of a respective side wall of the connector housing 512. In certain embodiments, the bottom portion 524 enhances the structure integrity of the mounting component 510.

In certain embodiments, the connector housing 512 includes a connector housing die 560, a connector housing backplane portion 562, a connector housing backplane tray 564, or a combination thereof. In certain embodiments, the connector housing 512 includes a first side wall 566, a second side wall 568, or a combination thereof. In certain embodiments, a first side of the mounting component 510 is mounted to an inside edge of the first side wall 566. In certain embodiments, a second side of the mounting component is mounted to an inside edge of the second side wall 568. In certain embodiments, the first side wall 566 defines one or more apertures via which fasteners mount the mounting component 510 to the inside edge of the first side wall 566. In certain embodiments, the second side wall 568 defines one or more apertures via which fasteners mount the mounting component 510 to the inside edge of the second side wall 568.

In certain embodiments, the connector housing includes one or more connector housing inside walls 570. In certain embodiments, the connector housing die 560 include the first side wall 566, the second side wall 568, the connector housing inside walls 570, or a combination thereof. In certain embodiments, the first side wall 566, the second side wall 568, the inside walls 570 are configured as a single piece of material. In certain embodiments, the connector housing backplane portion 562 includes storage device connector base receiving connectors 572, storage device system connectors 574, or a combination thereof.

In certain embodiments, each connector cable 514 includes one or more storage device connectors 580, one or more connector cables 582, one or more system connectors 584 or a combination thereof. In certain embodiments, the one or more storage device connectors 580, the one or more connector cables 582, the one or more system connectors 584, or a combination thereof, conform to an EDSFF specification. In certain embodiments, the storage device connectors 580 include EDSFF type storage device connectors. In certain embodiments, the connector cables 582 include EDSFF type cables. In certain embodiments, the system connectors 584 include EDSFF type system connectors. In certain embodiments, each connector receptacle portion 542 of the connector housing 512 is configured to receive bottom portion of a respective storage device connector 580 of a connector cable 514.

In certain embodiments, the multi-functional mounting components 430 secure EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitate backplane module installation and removal.

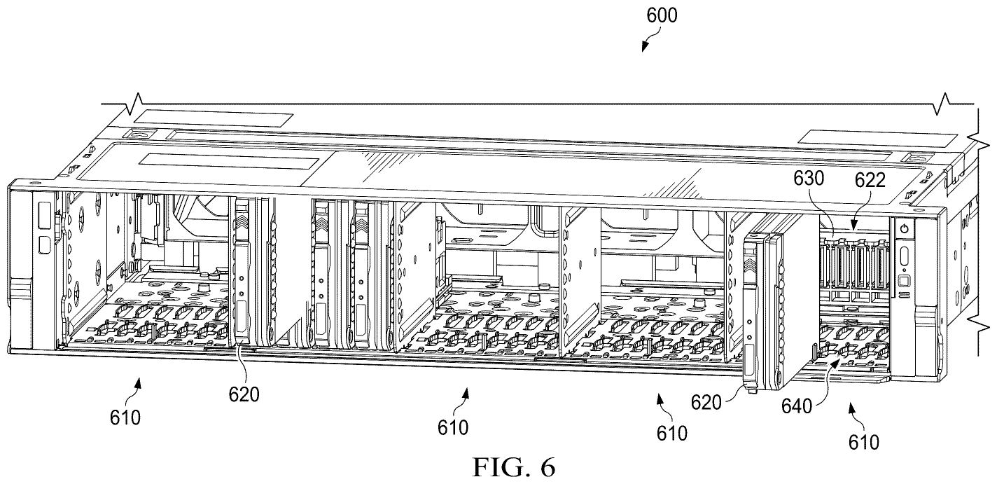

FIG. 6 shows a perspective view of a rear portion 600 of a server type information handling system having one or more drive systems 610 in accordance with the present disclosure.

In certain embodiments, the one or more of the drive systems 610 conform to a particular storage system specification. In certain embodiments, the drive systems include one or more storage devices 620, one or more drive mounting systems 622, or a combination thereof. In certain embodiments, the storage devices 620 and the storage system mounting system 622 conform to a particular storage system specification. In certain embodiments, the storage system specification includes the EDSFF storage system specification. In certain embodiments, the storage device mounting system 622 includes one or more multi-functional modular mounting components 630.

In certain embodiments, the drive mounting system 622 implements one or more slots 640 via which storage devices 620 may be mounted within a respective drive system 610. In certain embodiments, the drive mounting system 622 is orthogonal to the storage devices 610 as the drive mounting system extends substantially perpendicular to the storage devices 610. Accordingly, the drive mounting system 622 is perpendicular to the storage devices 610 at the point of intersection between the drive mounting system 622 and the inserted storage device 610.

In certain embodiments, the multi-functional mounting components 630 secure EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitates backplane module installation and removal. In certain embodiments, the storage devices 610 correspond to a 2T height.

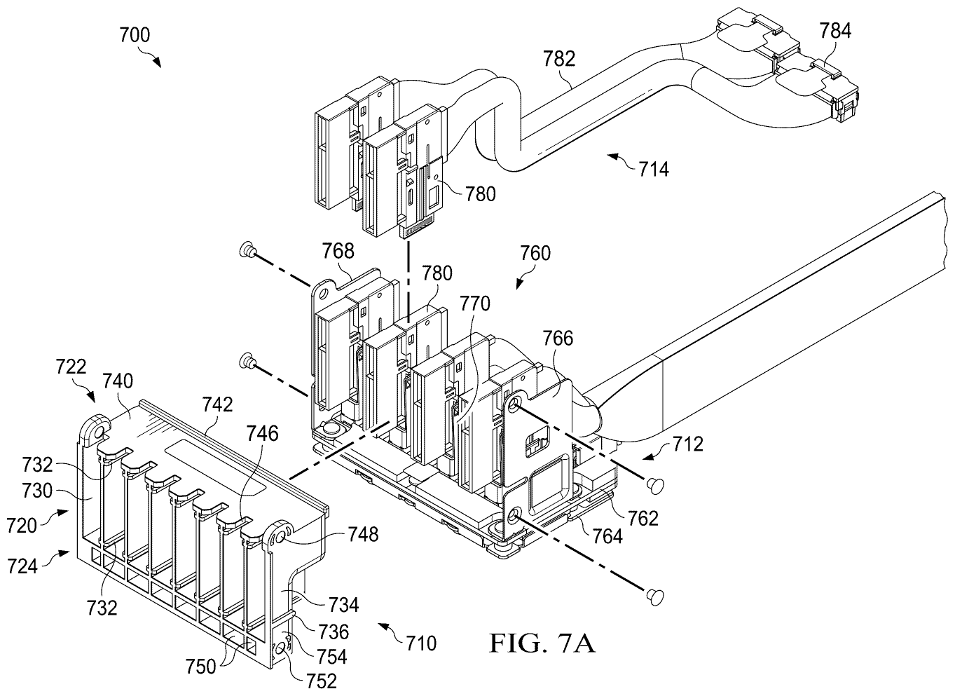

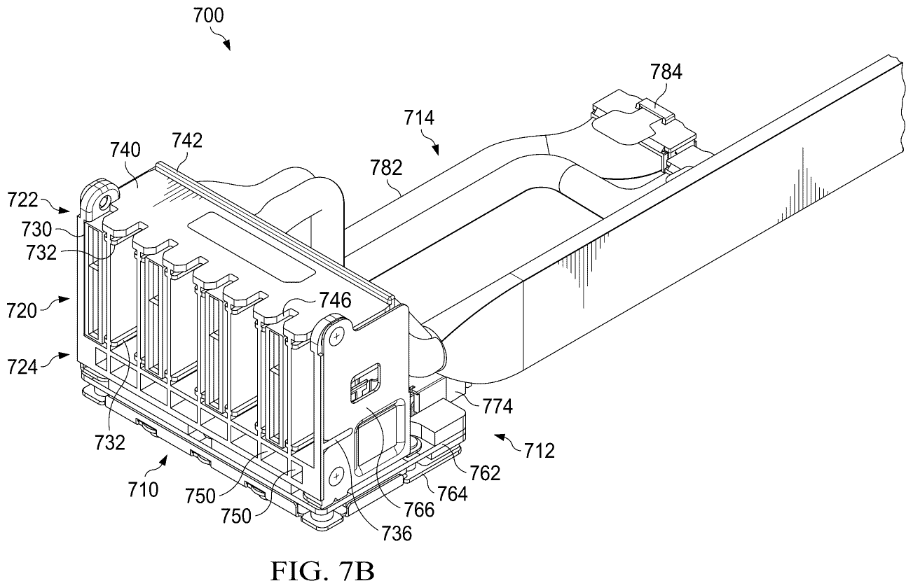

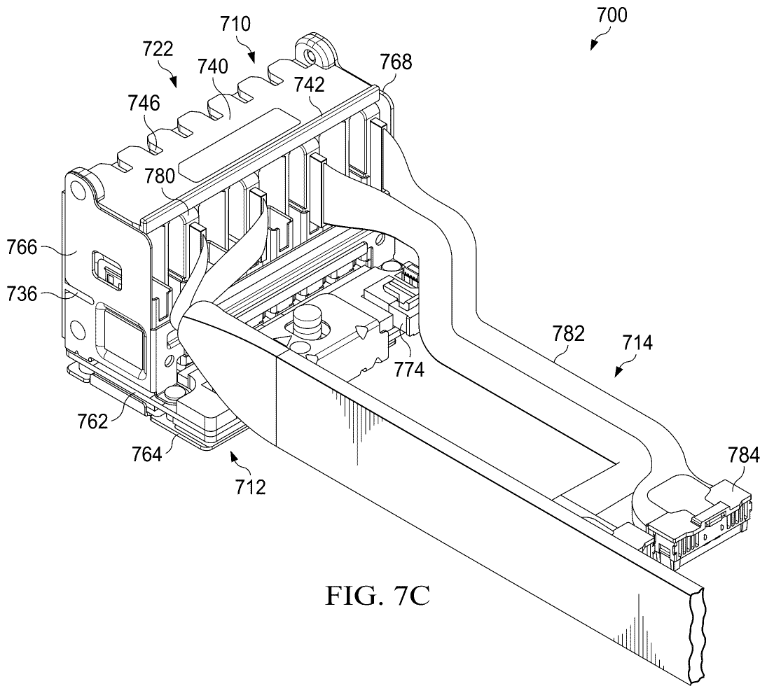

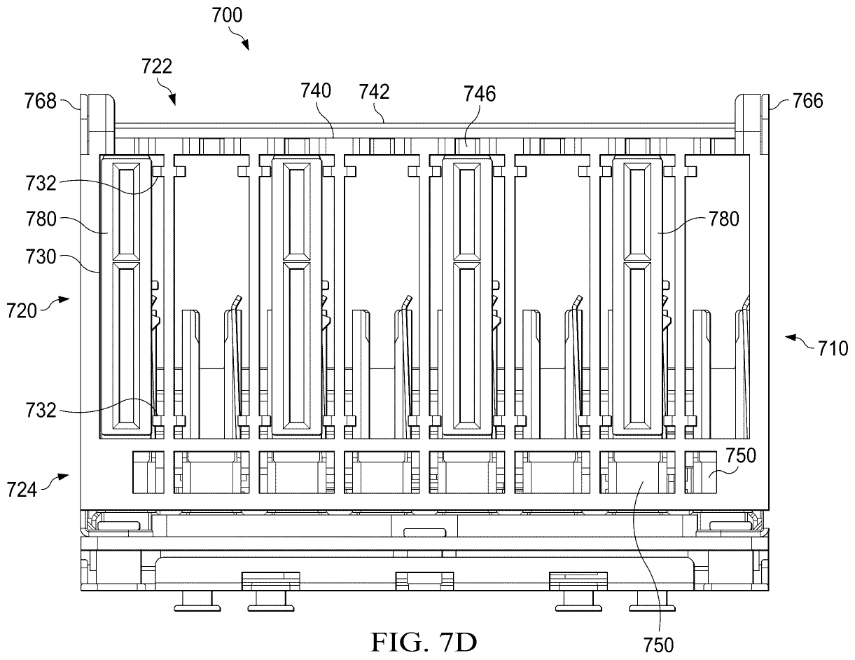

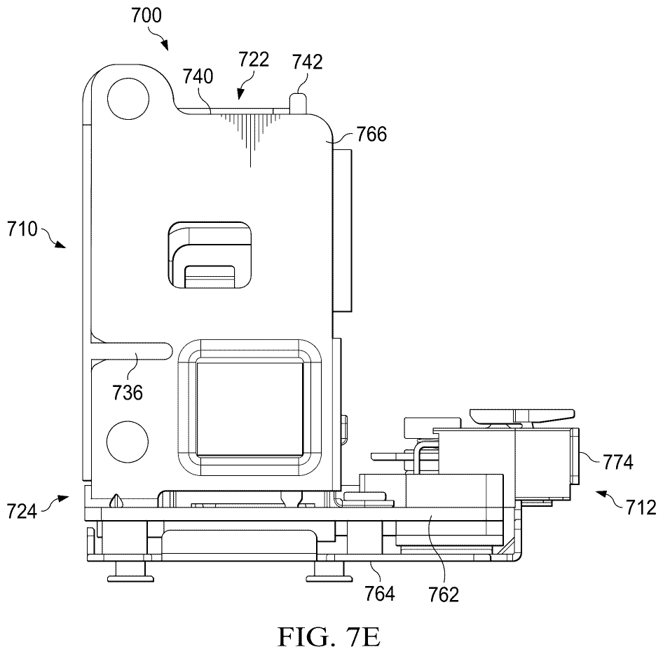

FIGS. 7A, 7B, 7C, 7D and 7E, generally referred to as FIG. 7, a plurality of views of a drive mounting system 700. More specifically, FIG. 7A shows an exploded view a front perspective view of a drive mounting system 700. FIG. 7B shows a front perspective view of a drive mounting system 700. FIG. 7C shows a rear perspective view of a drive mounting system 700. FIG. 7D shows a front view of a drive mounting system 700. FIG. 7E shows a side view of a drive mounting system 700.

In certain embodiments, the drive mounting system 700 includes a mounting component 710, a connector housing 712, and one or more connector cables 714. In certain embodiments, the mounting component 710 is physically coupled to the connector housing 712. In certain embodiments, the connector housing 712 defines a fixed pitch between respective connector receptacle portions 742 of the connector housing 712. In certain embodiments, the mounting component 710, the connector housing 712, the connector cables 714, or a combination thereof, correspond to a 2C2T form factor of the EDSFF specification (also referred to as a single connector, single slot form factor). In certain embodiments, the fixed pitch between the respective connector receptable portions correspond to a 2C2T form factor of the EDSFF specification. In certain embodiments, the drive mounting system 700 is configured to mount up to four storage devices. In certain embodiments, one or more of the four storage devices correspond to the EDSFF specification.

In certain embodiments, the mounting component 710 functions as a mounting component. In certain embodiments, the mounting component 710 includes a connector aperture portion 720, a top panel portion 722, a bottom portion 724, or a combination thereof. In certain embodiments, the connector aperture portion 720 is contiguous with the top panel portion 722. In certain embodiments, the top panel portion 722 extends substantially perpendicularly from the connector aperture portion 720. In certain embodiments, the connector aperture portion 720 is contiguous with the bottom panel portion 724. In certain embodiments, the bottom panel portion extends substantially linearly from the connector aperture portion 720. In certain embodiments, the connector aperture portion 720, the top panel portion 722, the bottom portion 724, or a combination thereof, are configured from a single piece of material. In certain embodiments, the connector aperture portion 720, the top panel portion 722, the bottom portion 724, or a combination thereof, are configured from plastic.

In certain embodiments, the connector aperture portion 720 includes a connector aperture portion housing which defines one or more longitudinally shaped connector apertures 730. In certain embodiments, the one or more longitudinally shaped connector apertures 730 are spaced apart by a predefined pitch. In certain embodiments, the predefined pitch corresponds to the fixed pitch defined by the connector housing 712. In certain embodiments, the connector apertures 730 include one or more side wall connector apertures, one or more interior connector apertures, or a combination thereof. In certain embodiments, the one or more side wall connector apertures are positioned at a side wall of the mounting component. In certain embodiments, the side wall connector apertures include a left side wall connector aperture, a right side wall connector aperture, or a combination thereof. In certain embodiments, the interior connector apertures are positioned between the one or more side wall apertures.

In certain embodiments, the one or more longitudinally shaped connector apertures 730 include one or more rib projections 732. In certain embodiments, the rib projections 732 include a top rib projection, a bottom rib projection, or a combination thereof. In certain embodiments, the one or more side wall connector apertures have a corresponding side wall connector aperture rib configuration. In certain embodiments, the one or more interior connector apertures have a corresponding interior connector aperture rib configuration.

In certain embodiments, the connector aperture portion 720 defines side recesses 734. In certain embodiments, the side recesses 734 mate with an inside edge of a respective side wall of the connector housing 712. In certain embodiments, one or both sides of the connector aperture portion 720 include respective mating projections 736. In certain embodiments, the respective mating projections 736 mate with a slot defined by a respective side wall of the connector housing 712.

In certain embodiments, the top portion 722 includes a top portion panel 740 which extends substantially perpendicularly from the connector aperture portion housing. In certain embodiments, the top portion panel 740 includes a rib component 742. In certain embodiments, the rib component 742 extends across a rear edge of the top panel portion 740. In certain embodiments, the top portion panel 740 defines one or more slots 746. In certain embodiments, the one or more slots 746 correspond to respective connector apertures 730. In certain embodiments, the one or more slots 746 enable observation of whether a connector is installed in a respective connector position of connector housing 612. In certain embodiments, the top portion 722 includes fastener receptors 748 to which a top set of fasteners attach the mounting component 710 to the connector housing 712. In certain embodiments, the top portion 722 enhances the structure integrity of the mounting component 710.

In certain embodiments, the bottom portion 724 includes a bottom portion housing which defines one or more airflow apertures 750. In certain embodiments, the some or all of the one or more airflow apertures 750 are spaced apart by a predefined pitch. In certain embodiments, the predefined pitch corresponds to the fixed pitch defined by the connector housing 712. In certain embodiments, the airflow apertures 750 include one or more side wall connector apertures, one or more interior connector apertures, or a combination thereof. In certain embodiments, the one or more side wall connector apertures are positioned at a side wall of the mounting component 710. In certain embodiments, the side wall connector apertures 752 include a left side wall connector aperture, a right side wall connector aperture, or a combination thereof. In certain embodiments, the interior connector apertures are positioned between the one or more side wall apertures. In certain embodiments, the one or more side wall apertures are positioned next to a side wall portion of the bottom portion housing. In certain embodiments, the bottom portion 724 includes fastener receptors to which a bottom set of fasteners attach the mounting component 710 to the connector housing 712. In certain embodiments, the bottom portion 724 defines side recesses 754. In certain embodiments, the side recesses mate with an inside edge of a respective side wall of the connector housing 712. In certain embodiments, the bottom portion 724 enhances the structure integrity of the mounting component 710.

In certain embodiments, the connector housing 712 includes a connector housing die 760, a connector housing backplane portion 762, a connector housing backplane tray 764, or a combination thereof. In certain embodiments, the connector housing 712 includes a first side wall 766, a second side wall 768, or a combination thereof. In certain embodiments, a first side of the mounting component 710 is mounted to an inside edge of the first side wall 766. In certain embodiments, a second side of the mounting component is mounted to an inside edge of the second side wall 768. In certain embodiments, the first side wall 766 defines one or more apertures via which fasteners mount the mounting component 710 to the inside edge of the first side wall 766. In certain embodiments, the second side wall 768 defines one or more apertures via which fasteners mount the mounting component 710 to the inside edge of the second side wall 768.

In certain embodiments, the connector housing includes one or more connector housing inside walls 770. In certain embodiments, the connector housing die 760 include the first side wall 766, the second side wall 768, the connector housing inside walls 770, or a combination thereof. In certain embodiments, the first side wall 766, the second side wall 768, the inside walls 770 are configured as a single piece of material. In certain embodiments, the connector housing backplane portion 762 includes storage device connector base receiving connectors 772, storage device system connectors 774, or a combination thereof.

In certain embodiments, each connector cable 714 includes one or more storage device connectors 780, one or more connector cables 782, one or more system connectors 784 or a combination thereof. In certain embodiments, the one or more storage device connectors 780, the one or more connector cables 782, the one or more system connectors 784, or a combination thereof, conform to an EDSFF specification. In certain embodiments, the storage device connectors 780 include EDSFF type storage device connectors. In certain embodiments, the connector cables 782 include EDSFF type cables. In certain embodiments, the system connectors 784 include EDSFF type system connectors. In certain embodiments, each connector receptacle portion 742 of the connector housing 712 is configured to receive bottom portion of a respective storage device connector 780 of a connector cable 714.

In certain embodiments, the multi-functional mounting components 630 secure EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitate backplane module installation and removal.

In certain embodiments, the multi-functional mounting components 630 secure EDSFF type cables and connectors to meet sound and vibration (S&V) type test requirements. In certain embodiments, the EDSFF type cables and connectors include orthogonal-hybrid cables and connectors. In certain embodiments, the EDSFF type cables include EDSFF 2C type cable which provides improved connection stability even though the 2C type connectors are taller than 1C type connectors. In certain embodiments, the multi-functional mounting component facilitate backplane module installation and removal.

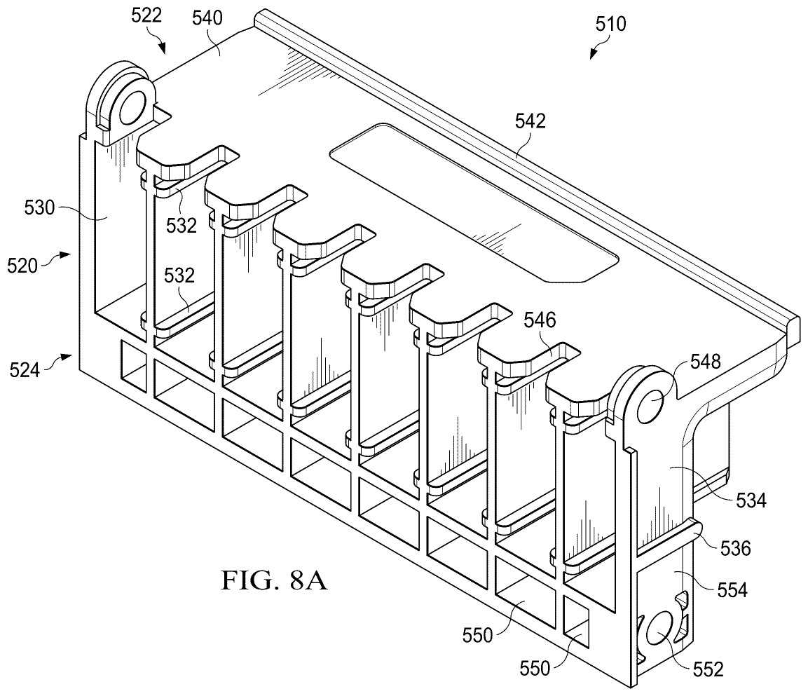

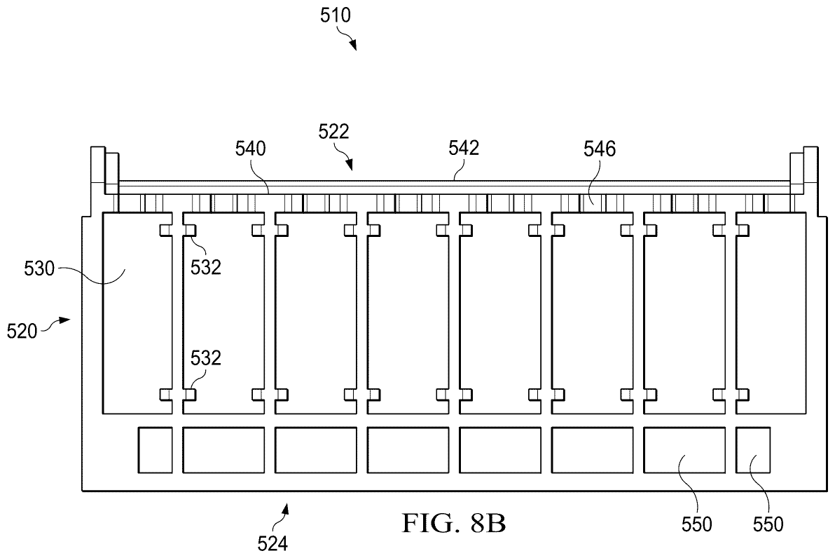

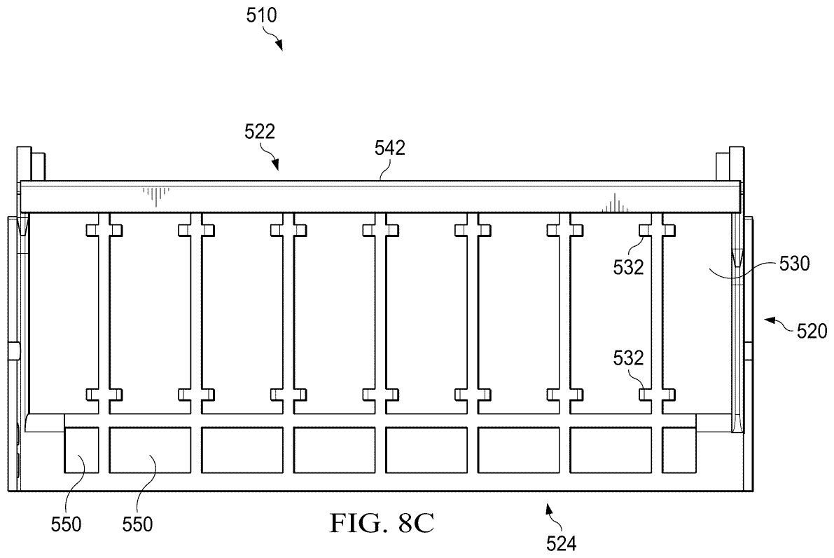

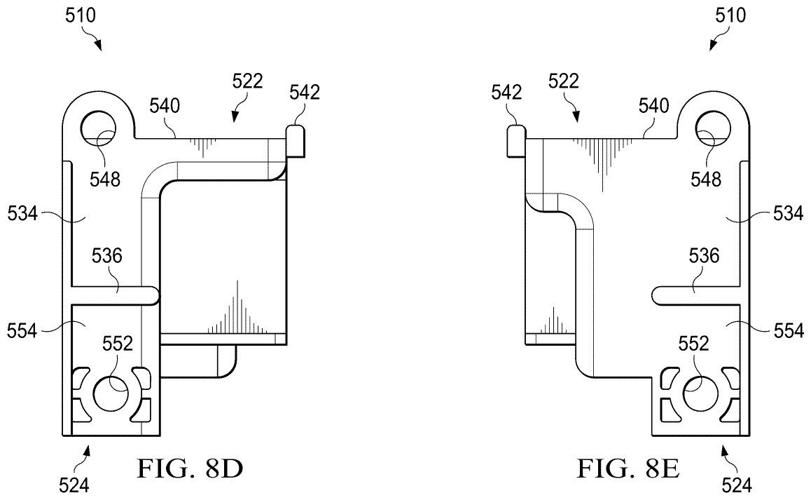

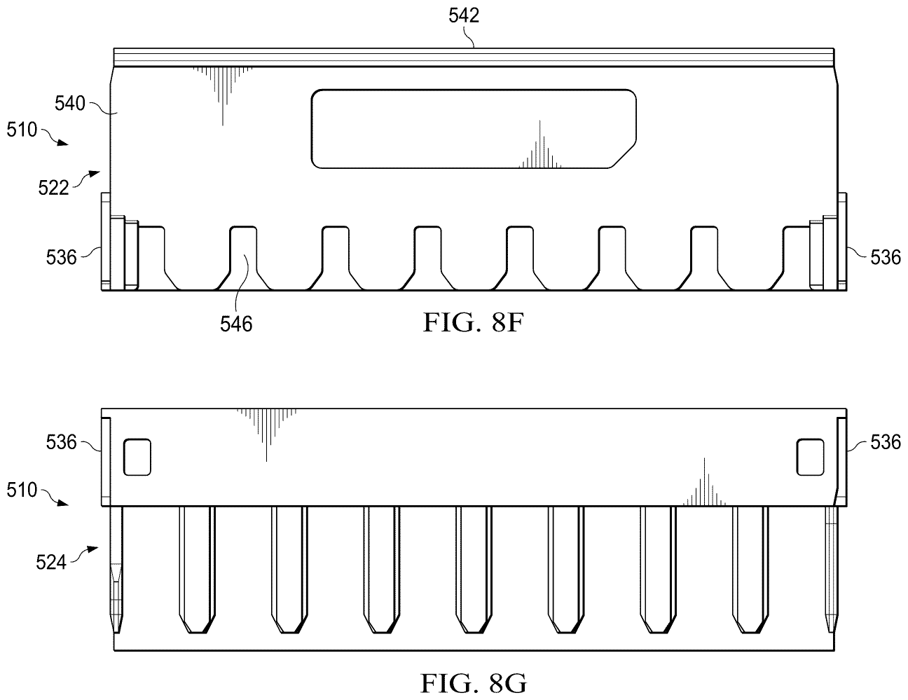

FIGS. 8A, 8B, 8C, 8D, 8E, 8F and 8G, generally referred to as FIG. 8, respectively show views of a mounting component 800. More specifically, FIG. 8A shows a front perspective view of the mounting component 800 of a drive mounting system. FIG. 8B shows a front view of the mounting component 800 of a drive mounting system. FIG. 8C shows a rear view of the mounting component 800 of a drive mounting system. FIG. 8D shows a top view of the mounting component 800 of a drive mounting system. FIG. 8E shows a bottom view of the mounting component 800 of a drive mounting system. FIG. 8F shows a right view of the mounting component 800 of a drive mounting system. FIG. 8G shows a left view of a mounting component of a drive mounting system. In certain embodiments, the mounting component is configured to function with a EDSFF 1C type drive mounting system. In certain embodiments, the mounting component 800 functions as a backplane mounting component.

In certain embodiments, the mounting component 800 includes a connector aperture portion 820, a top panel portion 822, a bottom portion 824, or a combination thereof. In certain embodiments, the connector aperture portion 820 is contiguous with the top panel portion 822. In certain embodiments, the top panel portion 822 extends substantially perpendicularly from the connector aperture portion 820. In certain embodiments, the connector aperture portion 820 is contiguous with the bottom panel portion 824. In certain embodiments, the bottom panel portion extends substantially linearly from the connector aperture portion 820. In certain embodiments, the connector aperture portion 820, the top panel portion 822, the bottom portion 824, or a combination thereof, are configured from a single piece of material. In certain embodiments, the connector aperture portion 820, the top panel portion 822, the bottom portion 824, or a combination thereof, are configured from plastic.

In certain embodiments, the connector aperture portion 820 includes a connector aperture portion housing which defines one or more longitudinally shaped connector apertures 830. In certain embodiments, the one or more longitudinally shaped connector apertures 830 are spaced apart by a predefined pitch. In certain embodiments, the predefined pitch corresponds to the fixed pitch defined by the connector housing 812. In certain embodiments, the connector apertures 830 include one or more side wall connector apertures, one or more interior connector apertures, or a combination thereof. In certain embodiments, the one or more side wall connector apertures are positioned at a side wall of the mounting component. In certain embodiments, the side wall connector apertures include a left side wall connector aperture, a right side wall connector aperture, or a combination thereof. In certain embodiments, the interior connector apertures are positioned between the one or more side wall apertures.

In certain embodiments, the one or more longitudinally shaped connector apertures 830 a rib projection configuration which include one or more rib projections 832. In certain embodiments, the rib projections include 832 include a top rib projection, a bottom rib projection, or a combination thereof. In certain embodiments, the one or more side wall connector apertures have a corresponding side wall connector aperture rib configuration. In certain embodiments, the side wall connector aperture rib configuration includes one or more rib projections on one side of the side wall connector aperture. In certain embodiments, the one or more interior connector apertures have a corresponding interior connector aperture rib configuration. In certain embodiments, the interior connector aperture rib configuration include one or more rib projections on both sides of the interior connector aperture.

In certain embodiments, the connector aperture portion 820 defines side recesses 834. In certain embodiments, the side recesses 834 mate with an inside edge of a respective side wall of the connector housing 812. In certain embodiments, one or both sides of the connector aperture portion 820 include respective mating projections 836. In certain embodiments, the respective mating projections 836 mate with a slot defined by a respective side wall of the connector housing 812.

In certain embodiments, the top portion 822 includes a top portion panel 840 which extends substantially perpendicularly from the connector aperture portion housing. In certain embodiments, the top portion panel 840 includes a rib component 842. In certain embodiments, the rib component 842 extends across a rear edge of the top panel portion 840. In certain embodiments, the top portion panel 840 defines one or more slots 846. In certain embodiments, the one or more slots 846 correspond to respective connector apertures 830. In certain embodiments, the one or more slots 846 enable observation of whether a connector is installed in a respective connector position of connector housing 612. In certain embodiments, the top portion 822 includes fastener receptors 848 to which a top set of fasteners attach the mounting component 800 to the connector housing 812. In certain embodiments, the top portion 822 enhances the structure integrity of the mounting component 800.

In certain embodiments, the bottom portion 824 includes a bottom portion housing which defines one or more airflow apertures 850. In certain embodiments, the some or all of the one or more airflow apertures 850 are spaced apart by a predefined pitch. In certain embodiments, the predefined pitch corresponds to the fixed pitch defined by the connector housing 812. In certain embodiments, the airflow apertures 850 include one or more side wall connector apertures, one or more interior connector apertures, or a combination thereof. In certain embodiments, the one or more side wall connector apertures are positioned at a side wall of the mounting component 800. In certain embodiments, the side wall connector apertures 852 include a left side wall connector aperture, a right side wall connector aperture, or a combination thereof. In certain embodiments, the interior connector apertures are positioned between the one or more side wall apertures. In certain embodiments, the one or more side wall apertures are positioned next to a side wall portion of the bottom portion housing. In certain embodiments, the bottom portion 824 includes fastener receptors to which a bottom set of fasteners attach the mounting component 800 to the connector housing 812. In certain embodiments, the bottom portion 824 defines side recesses 854. In certain embodiments, the side recesses mate with an inside edge of a respective side wall of the connector housing 812. In certain embodiments, the bottom portion 824 enhances the structure integrity of the mounting component 800.

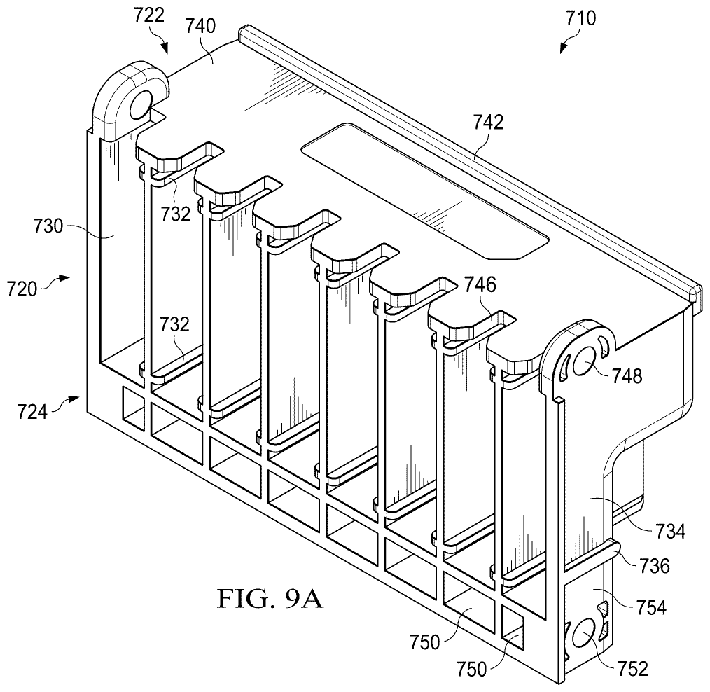

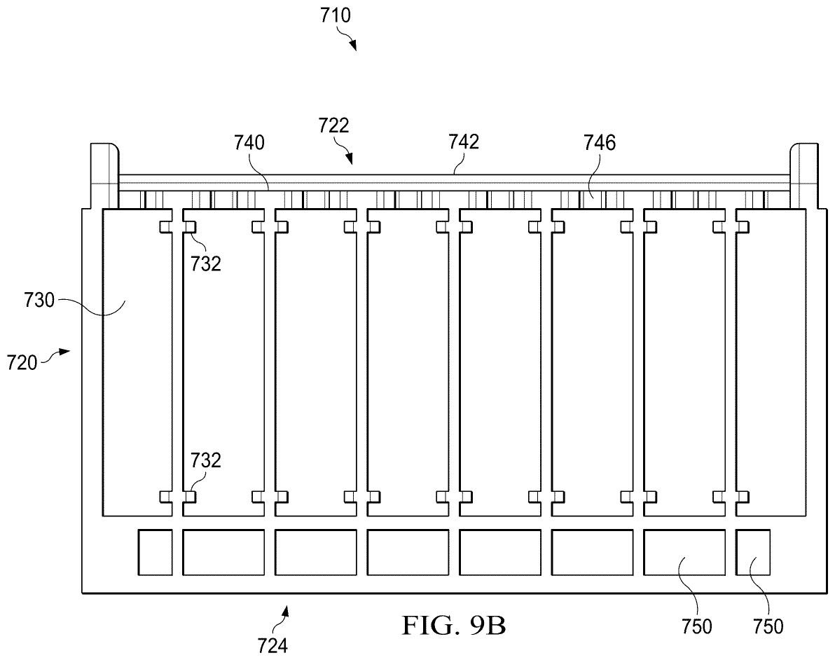

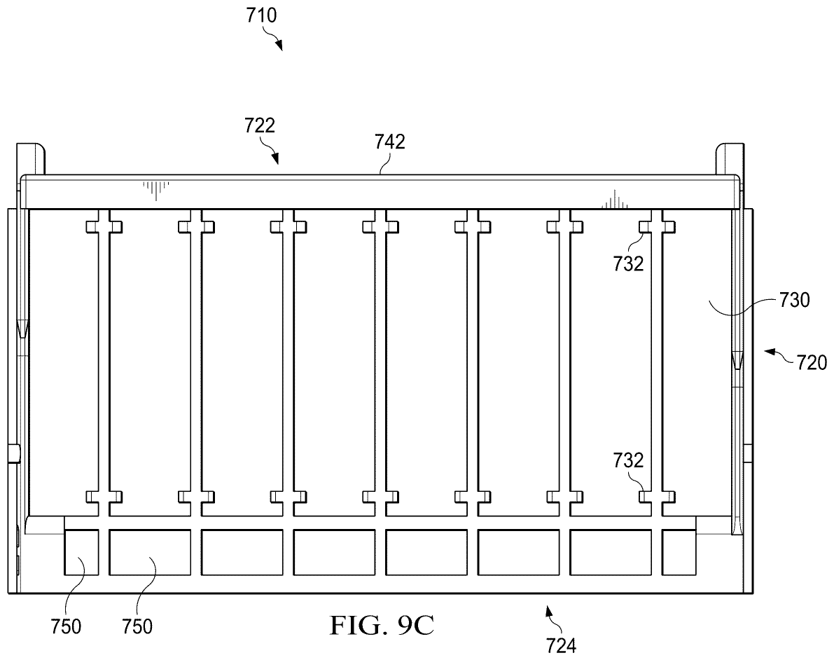

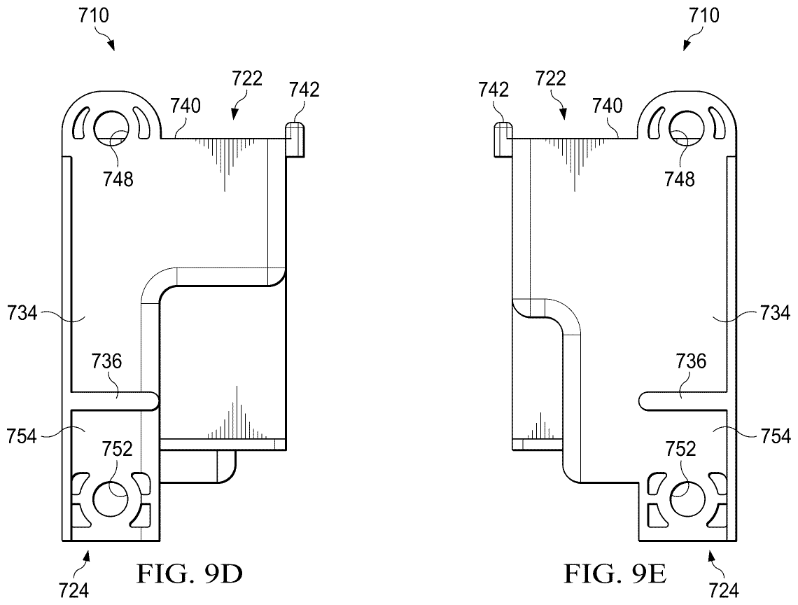

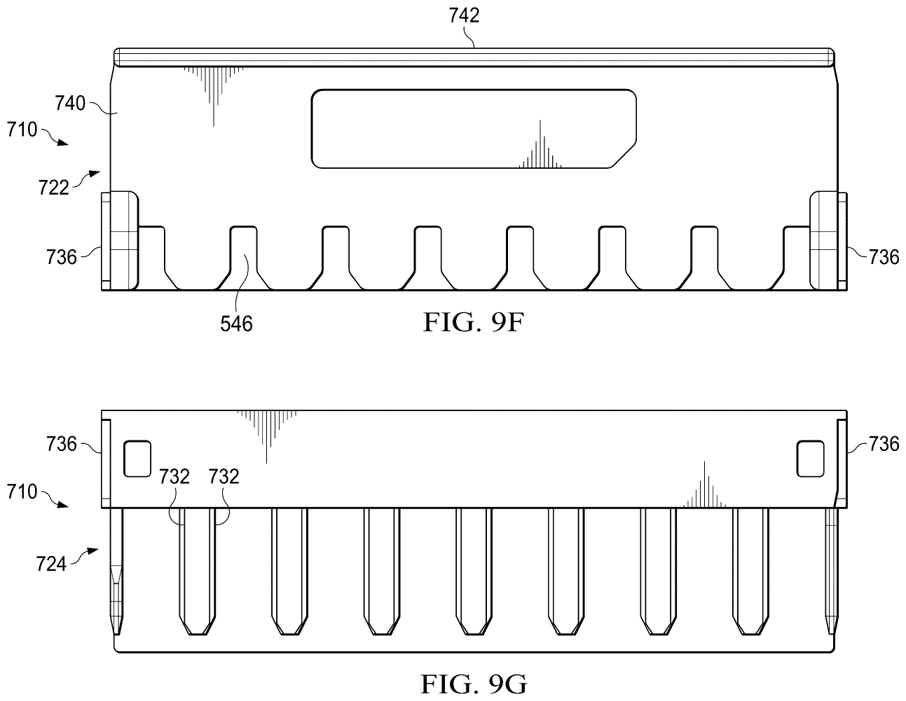

FIGS. 9A, 9B, 9C, 9D, 9E, 9F and 9G, generally referred to as FIG. 9, respectively show views of a mounting component 900. More specifically, FIG. 9A shows a front perspective view of the mounting component 900 of a drive mounting system. FIG. 9B shows a front view of the mounting component 900 of a drive mounting system. FIG. 9C shows a rear view of the mounting component 900 of a drive mounting system. FIG. 9D shows a top view of the mounting component 900 of a drive mounting system. FIG. 9E shows a bottom view of the mounting component 900 of a drive mounting system. FIG. 9F shows a right view of the mounting component 900 of a drive mounting system. FIG. 9G shows a left view of a mounting component of a drive mounting system. In certain embodiments, the mounting component is configured to function with a EDSFF 2C type drive mounting system.

In certain embodiments, the mounting component 900 includes a connector aperture portion 920, a top panel portion 922, a bottom portion 924, or a combination thereof. In certain embodiments, the connector aperture portion 920 is contiguous with the top panel portion 922. In certain embodiments, the top panel portion 922 extends substantially perpendicularly from the connector aperture portion 920. In certain embodiments, the connector aperture portion 920 is contiguous with the bottom panel portion 924. In certain embodiments, the bottom panel portion extends substantially linearly from the connector aperture portion 920. In certain embodiments, the connector aperture portion 920, the top panel portion 922, the bottom portion 924, or a combination thereof, are configured from a single piece of material. In certain embodiments, the connector aperture portion 920, the top panel portion 922, the bottom portion 924, or a combination thereof, are configured from plastic.

In certain embodiments, the connector aperture portion 920 includes a connector aperture portion housing which defines one or more longitudinally shaped connector apertures 930. In certain embodiments, the one or more longitudinally shaped connector apertures 930 are spaced apart by a predefined pitch. In certain embodiments, the predefined pitch corresponds to the fixed pitch defined by the connector housing 912. In certain embodiments, the connector apertures 930 include one or more side wall connector apertures, one or more interior connector apertures, or a combination thereof. In certain embodiments, the one or more side wall connector apertures are positioned at a side wall of the mounting component. In certain embodiments, the side wall connector apertures include a left side wall connector aperture, a right side wall connector aperture, or a combination thereof. In certain embodiments, the interior connector apertures are positioned between the one or more side wall apertures.

In certain embodiments, the one or more longitudinally shaped connector apertures 930 a rib projection configuration which include one or more rib projections 932. In certain embodiments, the rib projections include 932 include a top rib projection, a bottom rib projection, or a combination thereof. In certain embodiments, the one or more side wall connector apertures have a corresponding side wall connector aperture rib configuration. In certain embodiments, the side wall connector aperture rib configuration includes one or more rib projections on one side of the side wall connector aperture. In certain embodiments, the one or more interior connector apertures have a corresponding interior connector aperture rib configuration. In certain embodiments, the interior connector aperture rib configuration includes one or more rib projections on both sides of the interior connector aperture.

In certain embodiments, the connector aperture portion 920 defines side recesses 934. In certain embodiments, the side recesses 934 mate with an inside edge of a respective side wall of the connector housing 912. In certain embodiments, one or both sides of the connector aperture portion 920 include respective mating projections 936. In certain embodiments, the respective mating projections 936 mate with a slot defined by a respective side wall of the connector housing 912.

In certain embodiments, the top portion 922 includes a top portion panel 940 which extends substantially perpendicularly from the connector aperture portion housing. In certain embodiments, the top portion panel 940 includes a rib component 942. In certain embodiments, the rib component 942 extends across a rear edge of the top panel portion 940. In certain embodiments, the top portion panel 940 defines one or more slots 946. In certain embodiments, the one or more slots 946 correspond to respective connector apertures 930. In certain embodiments, the one or more slots 946 enable observation of whether a connector is installed in a respective connector position of connector housing 612. In certain embodiments, the top portion 922 includes fastener receptors 948 to which a top set of fasteners attach the mounting component 900 to the connector housing 912. In certain embodiments, the top portion 922 enhances the structure integrity of the mounting component 900.

In certain embodiments, the bottom portion 924 includes a bottom portion housing which defines one or more airflow apertures 950. In certain embodiments, the some or all of the one or more airflow apertures 950 are spaced apart by a predefined pitch. In certain embodiments, the predefined pitch corresponds to the fixed pitch defined by the connector housing 912. In certain embodiments, the airflow apertures 950 include one or more side wall connector apertures, one or more interior connector apertures, or a combination thereof. In certain embodiments, the one or more side wall connector apertures are positioned at a side wall of the mounting component 900. In certain embodiments, the side wall connector apertures 952 include a left side wall connector aperture, a right side wall connector aperture, or a combination thereof. In certain embodiments, the interior connector apertures are positioned between the one or more side wall apertures. In certain embodiments, the one or more side wall apertures are positioned next to a side wall portion of the bottom portion housing. In certain embodiments, the bottom portion 924 includes fastener receptors to which a bottom set of fasteners attach the mounting component 900 to the connector housing 912. In certain embodiments, the bottom portion 924 defines side recesses 954. In certain embodiments, the side recesses mate with an inside edge of a respective side wall of the connector housing 912. In certain embodiments, the bottom portion 924 enhances the structure integrity of the mounting component 900.

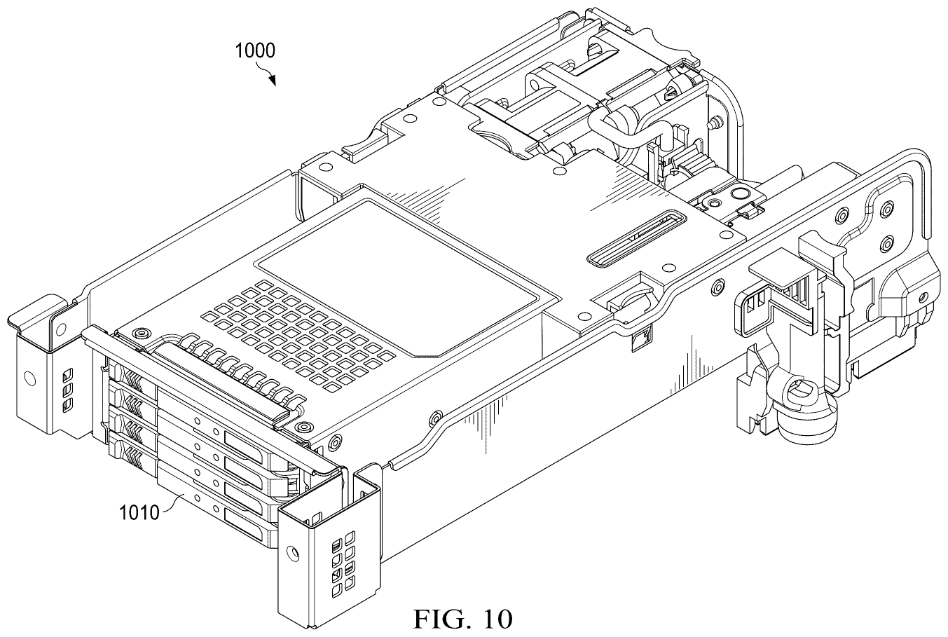

FIG. 10 shows a perspective view of a drive system 1000 in accordance with the present disclosure. More specifically, the drive system 1000 provides an implementation in which the drives 1010 are mounted horizontally within a server system. Accordingly, the drive system 100 includes a drive mounting system which is configured to horizontally mount the drives 1010.

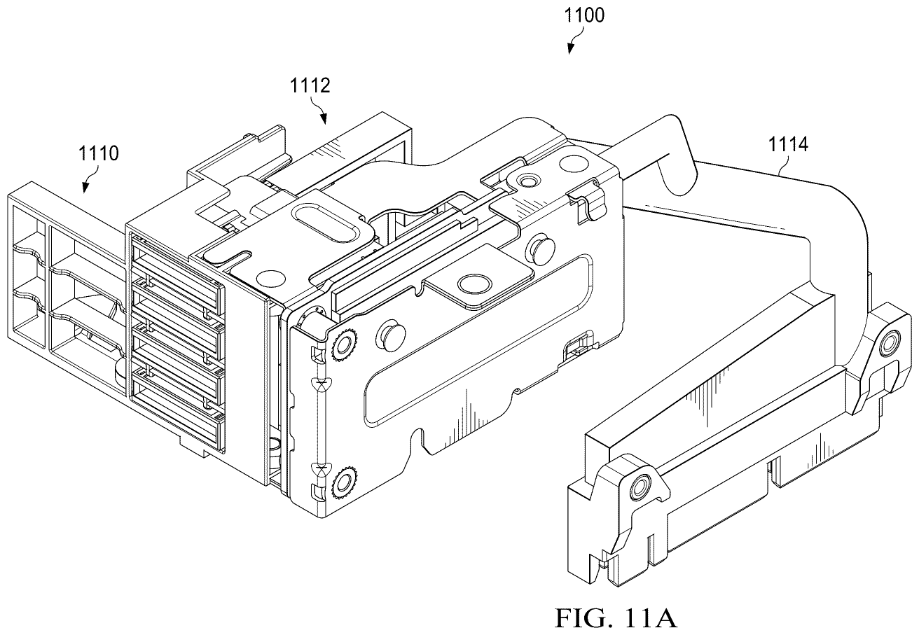

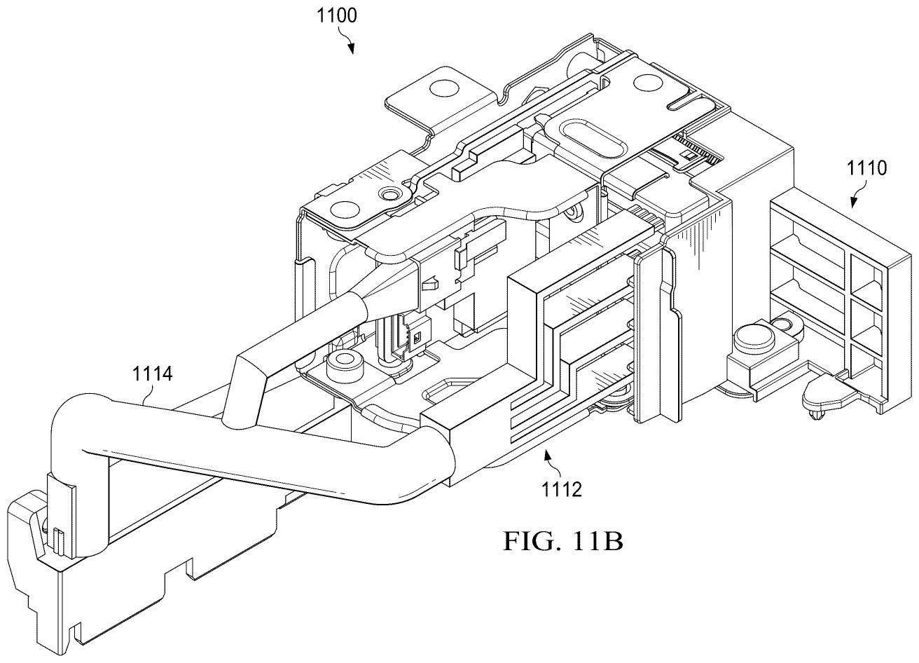

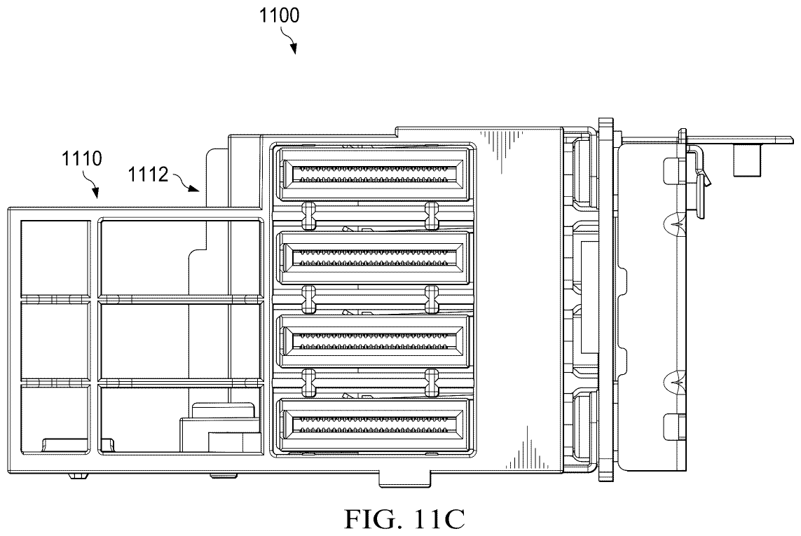

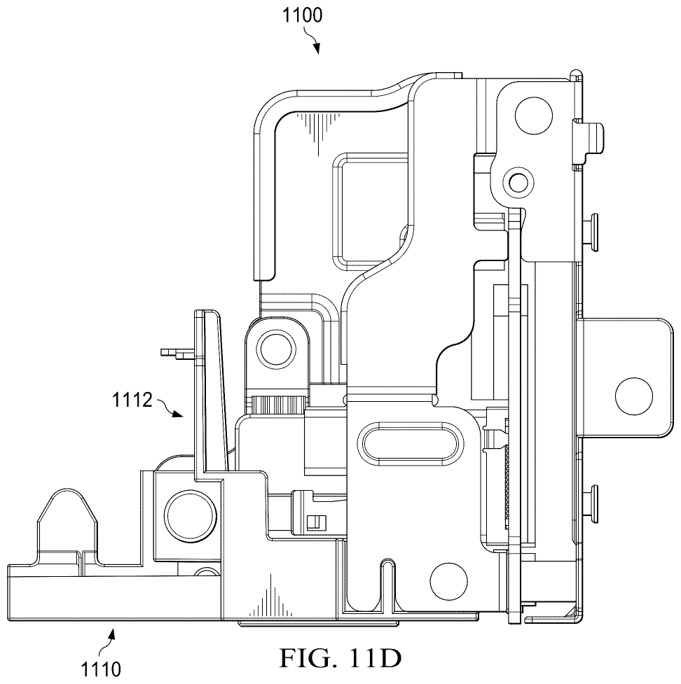

FIGS. 11A, 11B, 11C, and 11D, generally referred to as FIG. 11, respectively show a front perspective view, a rear perspective view, a front view and a side view of a drive mounting system in accordance with the present disclosure.

In certain embodiments, the drive mounting system 1100 includes a mounting component 1110, a connector housing 1112, and one or more connector cables 1114. In certain embodiments, the mounting component 1110 is physically coupled to the connector housing 1112. In certain embodiments, the connector housing 1112 defines a fixed pitch between respective connector receptacle portions 1142 of the connector housing 1112. In certain embodiments, the mounting component 1110, the connector housing 1112, the connector cables 1114, or a combination thereof, correspond to a modified 1C1T form factor of the EDSFF specification (also referred to as a single connector, single slot form factor). More specifically, the 1C1T form factor is modified to enable horizontal mounting of drives. In certain embodiments, the fixed pitch between the respective connector receptable portions correspond to a 1C1T form factor of the EDSFF specification. In certain embodiments, the drive mounting system 1100 is configured to mount up to four storage devices. In certain embodiments, one or more of the four storage devices correspond to the EDSFF specification.

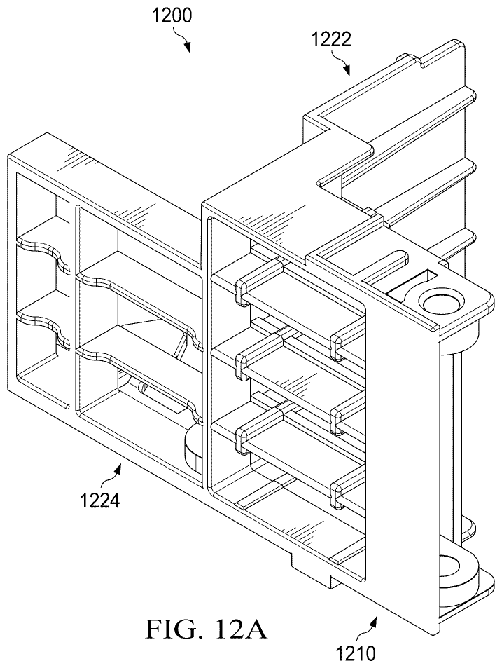

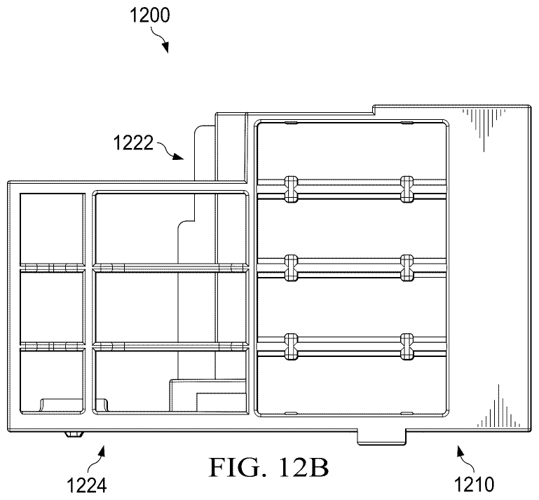

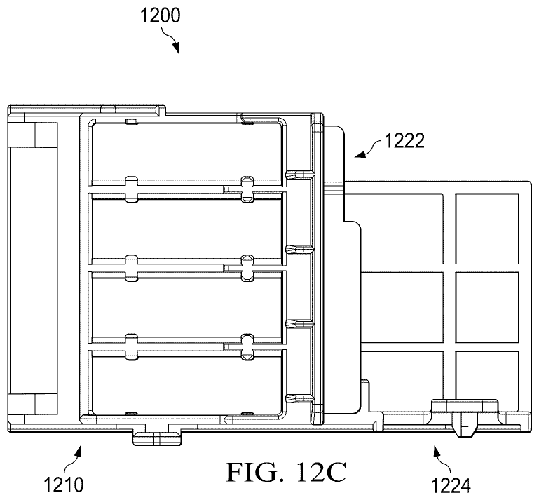

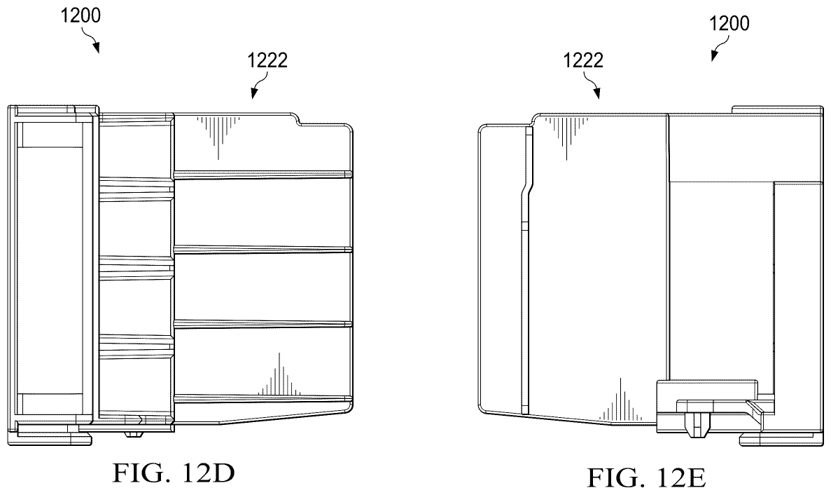

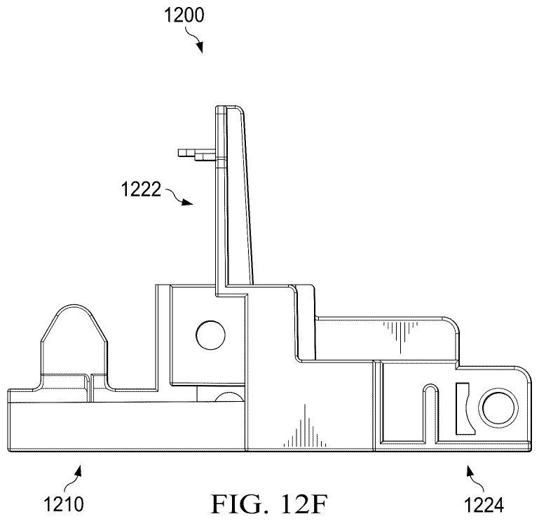

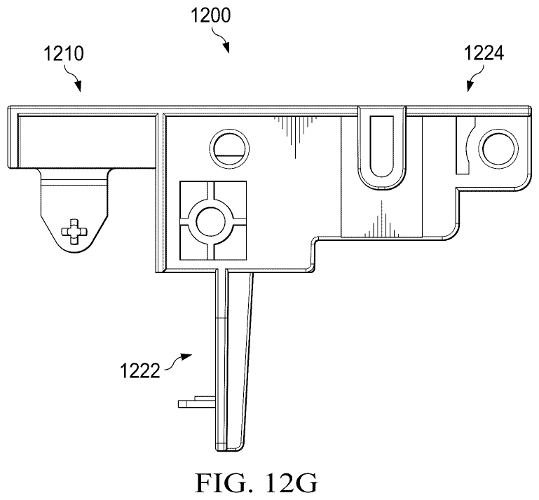

FIGS. 12A, 12B, 12C, 12D, 12E, 12F and 12G, generally referred to as FIG. 12, respectively show views of a mounting component 1200. More specifically, FIG. 12A shows a front perspective view of the mounting component 1200 of a drive mounting system. FIG. 12B shows a front view of the mounting component 1200 of a drive mounting system. FIG. 12C shows a rear view of the mounting component 1200 of a drive mounting system. FIG. 12D shows a top view of the mounting component 1200 of a drive mounting system. FIG. 12E shows a bottom view of the mounting component 1200 of a drive mounting system. FIG. 12F shows a right view of the mounting component 1200 of a drive mounting system. FIG. 12G shows a left view of a mounting component of a drive mounting system. In certain embodiments, the mounting component is configured to function with a modified EDSFF 1C type drive mounting system. More specifically, the mounting component is modified to enable horizontal mounting of drives.

In certain embodiments, the mounting component 1200 includes a connector aperture portion 1220, a mid-panel portion 1222, a side portion 1224, or a combination thereof. In certain embodiments, the connector aperture portion 1220 is contiguous with the mid panel portion 1222. In certain embodiments, the mid panel portion 1222 extends substantially perpendicularly from the connector aperture portion 1220. In certain embodiments, the connector aperture portion 1220 is contiguous with the side portion 1224. In certain embodiments, the side portion extends substantially linearly from the connector aperture portion 1220. In certain embodiments, the connector aperture portion 1220, the mid panel portion 1222, the side portion 1224, or a combination thereof, are configured from a single piece of material. In certain embodiments, the connector aperture portion 1220, the mid panel portion 1222, the side portion 1224, or a combination thereof, are configured from plastic.

In certain embodiments, the one or more longitudinally shaped connector apertures 930 a rib projection configuration which include one or more rib projections. In certain embodiments, the rib projections include a right side rib projection, a left side rib projection, or a combination thereof. In certain embodiments, one or more side wall connector apertures have a corresponding top wall connector aperture rib configuration. In certain embodiments, the side wall connector aperture rib configuration includes one or more rib projections on one side of the side wall connector aperture. In certain embodiments, the one or more interior connector apertures have a corresponding interior connector aperture rib configuration. In certain embodiments, the interior connector aperture rib configuration includes one or more rib projections on both sides of the interior connector aperture.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A mounting component of a drive mounting system, comprising:
a connector aperture portion, the connector aperture portion comprising a connector aperture housing, the connector aperture housing defining a plurality of longitudinally shaped connector apertures, the plurality of longitudinally shaped connector apertures being spaced apart by a predefined pitch, the predefined pitch corresponding to a fixed pitch defined by a connector housing; and,
a top panel portion, top panel portion extending substantially perpendicularly from the connector aperture portion.

2. The mounting component of claim 1, wherein:
the plurality of longitudinally shaped connector apertures comprise a side wall connector aperture and an interior connector aperture.

3. The mounting component of claim 2, wherein:
at least some of the plurality of longitudinally shaped connector apertures comprising a rib projection configuration.

4. The mounting component of claim 3, wherein:
the side wall connector aperture comprises a first rib projection configuration and the interior connector aperture comprises a second rib projection configuration.

5. The mounting component of claim 1, further comprising:
a bottom portion, the bottom panel portion extending substantially linearly from the connector aperture portion.

6. The mounting component of claim 5, wherein:
the bottom portion comprises a bottom portion housing, the bottom portion housing defining a plurality of airflow apertures, at least some of the plurality of airflow apertures being spaced apart by the predefined pitch.

7. A drive mounting system comprising:
a connector housing; and,
a mounting component physically coupled to the connector housing, the mounting component comprising:
a connector aperture portion, the connector aperture portion comprising a connector aperture housing, the connector aperture housing defining a plurality of longitudinally shaped connector apertures, the plurality of longitudinally shaped connector apertures being spaced apart by a predefined pitch, the predefined pitch corresponding to a fixed pitch defined by a connector housing; and,
a top panel portion, top panel portion extending substantially perpendicularly from the connector aperture portion.

8. The drive mounting system of claim 7, wherein:
the plurality of longitudinally shaped connector apertures comprise a side wall connector aperture and an interior connector aperture.

9. The drive mounting system of claim 8, wherein:
at least some of the plurality of longitudinally shaped connector apertures comprising a rib projection configuration.

10. The drive mounting system of claim 9, wherein:
the side wall connector aperture comprises a first rib projection configuration and the interior connector aperture comprises a second rib projection configuration.

11. The drive mounting system of claim 7, wherein:
the mounting component further comprises a bottom portion, the bottom panel portion extending substantially linearly from the connector aperture portion.

12. The drive mounting system of claim 11, wherein:
the bottom portion comprises a bottom portion housing, the bottom portion housing defining a plurality of airflow apertures, at least some of the plurality of airflow apertures being spaced apart by the predefined pitch.

13. A system comprising:
a processor;
a data bus coupled to the processor;
a drive; and,
a drive mounting system mounting the drive, the drive mounting system comprising:
a connector housing; and,
a mounting component physically coupled to the connector housing, the mounting component comprising:
a connector aperture portion, the connector aperture portion comprising a connector aperture housing, the connector aperture housing defining a plurality of longitudinally shaped connector apertures, the plurality of longitudinally shaped connector apertures being spaced apart by a predefined pitch, the predefined pitch corresponding to a fixed pitch defined by a connector housing; and,
a top panel portion, top panel portion extending substantially perpendicularly from the connector aperture portion.

14. The system of claim 13, wherein:
the plurality of longitudinally shaped connector apertures comprise a side wall connector aperture and an interior connector aperture.

15. The system of claim 14, wherein:
at least some of the plurality of longitudinally shaped connector apertures comprising a rib projection configuration.

16. The system of claim 15, wherein:
the side wall connector aperture comprises a first rib projection configuration and the interior connector aperture comprises a second rib projection configuration.

17. The system of claim 13, wherein:
the mounting component further comprises a bottom portion, the bottom panel portion extending substantially linearly from the connector aperture portion.

18. The system of claim 17, wherein:
the bottom portion comprises a bottom portion housing, the bottom portion housing defining a plurality of airflow apertures, at least some of the plurality of airflow apertures being spaced apart by the predefined pitch.
